(19) United States
(12) Patent Application Publication
(10) Pub. No.: US 2025/0240009 A1
(43) Pub. Date: Jul. 24, 2025

(54) COMPACT HIGH POWER RADIO FREQUENCY (RF) SWITCH

(71) Applicant: GlobalFoundries U.S. Inc., Malta, NY (US)

(72) Inventors: Santosh Kumar Gedela, Bangalore (IN); Venkata Narayana Rao Vanukuru, Bangalore (IN)

(21) Appl. No.: 18/416,493

(22) Filed: Jan. 18, 2024

(51) Int. Cl. H03K 17/10; H03K 17/041; H03K 17/687

(52) U.S. Cl. CPC H03K 17/102; H03K 17/04106; H03K 17/6871

(57) ABSTRACT

A radio frequency (RF) switch includes a transistor stack with different sections having different configurations for achieving different parasitic capacitances. Specifically, a first section is connected to an input terminal and a second section is connected between the first section and an output terminal. The second section has over-gate gaps for reduced source-to-drain capacitance, whereas the first section does not. Additionally, gate-to-source/drain contact spacing can be larger in the second section than in the first section, transistor layout length can be longer in the second section than in the first section and/or source and drain interconnect interdigitation can be less in the second section than in the first section. Optionally, sub-sections of the series-connected transistors within the first and/or second sections also have different configurations. Thus, numbers and sizes of compensation capacitors within the switch and overall chip area consumed by the switch are reduced while maintaining a high Pmax.

### BACKGROUND

The present disclosure relates to switches and, more particularly, to embodiments of a compact high power radio frequency (RF) switch (e.g., a compact high power RF switch tuner).

RF switches (i.e., switches configured for RF operation) are often incorporated into transceiver front ends. RF switches typically include series-connected transistors (i.e., a stack of transistors) in order to accommodate high power RF input signals. However, beyond some input power level, adding transistors to the stack becomes less effective and compensation capacitors (e.g., back end of the line (BEOL) metal-insulator-metal capacitors (MIMCAPs)) also need to be incorporated into RF switch. Unfortunately, MIMCAPS can consume a significant amount of chip area.

### SUMMARY

Disclosed herein are embodiments of a radio frequency (RF) switch structure. In the disclosed embodiments, the RF switch structure can include an input terminal, an output terminal, and series-connected transistors between the input terminal and the output terminal. The series-connected transistors can include two sections (i.e., a first section and a second section). The first section can be connected to the input terminal. The second section can be connected between the first section and the output terminal. Transistors in the second section can be configured differently from transistors in the first section. For example, transistors in the first section can be devoid of any over-gate gaps, and transistors in the second section can have such over-gate gaps.

Some embodiments of an RF switch structure disclosed herein can include an input terminal, an output terminal, and series-connected transistors between the input terminal and the output terminal. The series-connected transistors can include two sections (i.e., a first section and a second section). The first section can be connected to the input terminal. The second section can be connected between the first section and the output terminal. Transistors in the second section can be configured differently from transistors in the first section. For example, transistor layout lengths can be longer in the second section than in the first section, transistor gate-to-source/drain contact spacings can be larger in the second section than in the first section, and only transistors in the second section can have over-gate gaps (i.e., transistors in the first section can be devoid of such over-gate gaps).

Some embodiments of an RF switch structure disclosed herein can include an input terminal, an output terminal, and series-connected transistors between the input terminal and the output terminal. The series-connected transistors can be semiconductor-on-insulator n-channel field effect transistors with multiple gate fingers. Furthermore, the series-connected transistors can include two sections (i.e., a first section and a second section). The first section can be connected to the input terminal. The second section can be connected between the first section and the output terminal. Transistors in the second section can be configured differently from transistors in the first section. For example, transistor layout lengths can be longer in the second section than in the first section, transistor gate-to-source/drain contact spacings can be larger in the second section than in the first section, and only transistors in the second section can have over-gate gaps (i.e., transistors in the first section can be devoid of such over-gate gaps).

It should be noted that all aspects, examples, and features of disclosed embodiments mentioned in the summary above can be combined in any technically possible way. That is, two or more aspects of any of the disclosed embodiments, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The present disclosure will be better understood from the following detailed description with reference to the drawings, which are not necessarily drawn to scale and in which:

FIGS. 1A and 1B are schematic diagrams illustrating RF switch circuits implemented in a fully depleted semiconductor-on-insulator processing technology platform and a partially depleted semiconductor-on-insulator processing technology platform, respectively;

FIG. 2 is a layout diagram illustrating one example of an RF switch structure;

FIG. 3 is a layout diagram illustrating one example of the essentially identical multi-finger field effect transistors (FETs) incorporated in the RF switch structure of FIG. 3;

FIG. 4 is a layout diagram illustrating a disclosed embodiment of an RF switch structure;

FIG. 5A-1, FIG. 5A-2, and FIG. 5A-3 are layout diagrams illustrating differently configured transistors in different sub-sections, respectively, of a first section of series-connected transistors in the RF switch structure of FIG. 4;

FIG. 5B-1 and FIG. 5B-2 are layout diagrams illustrating differently configured transistors in different sub-sections, respectively, of a second section of the series-connected transistors in the RF switch structure of FIG. 4;

FIG. 6.1 is a cross-section diagram illustrating a portion, including a single gate finger, of any of the transistors of FIG. 5A-1, FIG. 5A-2 and FIG. 5A-3 when implemented as fully depleted semiconductor-on-insulator (FDSOI) transistors;

FIG. 6.2 is a cross-section diagram illustrating a portion, including a single gate finger, of a transistor of FIG. 5B-1 when implemented as an FDSOI transistor;

FIG. 6.3 is a cross-section diagram illustrating a portion, including a single gate finger, of the transistor of FIG. 5B-2 when implemented as an FDSOI transistor;

FIG. 6.4 is a cross-section diagram illustrating a portion, including a well tap, for any of the transistors of FIGS. 6.1-6.3;

FIG. 7.1 is a cross-section diagram illustrating a portion, including a single gate finger, of any of the transistors of FIG. 5A-1, FIG. 5A-2 and FIG. 5A-3 when implemented as partially depleted semiconductor-on-insulator (PDSOI) transistors;

FIG. 7.2 is a cross-section diagram illustrating a portion, including a single gate finger, of a transistor of FIG. 5B-1 when implemented as a PDSOI transistor;

FIG. 7.3 is a cross-section diagram illustrating a portion, including a single gate finger, of the transistor of FIG. 5B-2 when implemented as a PDSOI transistor;

FIG. 7.4 is a cross-section diagram illustrating a portion, including a body contact, for any of the transistors of FIGS. 7.1-7.3; and

FIGS. 8A-8C are graphs each illustrating first, second and third order harmonics for a corresponding one of three different RF switch structures, respectively.

### DETAILED DESCRIPTION

As mentioned above, RF switches typically include series-connected transistors (i.e., a stack of transistors) in order to accommodate high power RF input signals. However, beyond some input power level, adding transistors to the stack becomes less effective and compensation capacitors (e.g., BEOL MIMCAPs) also need to be incorporated into RF switch.

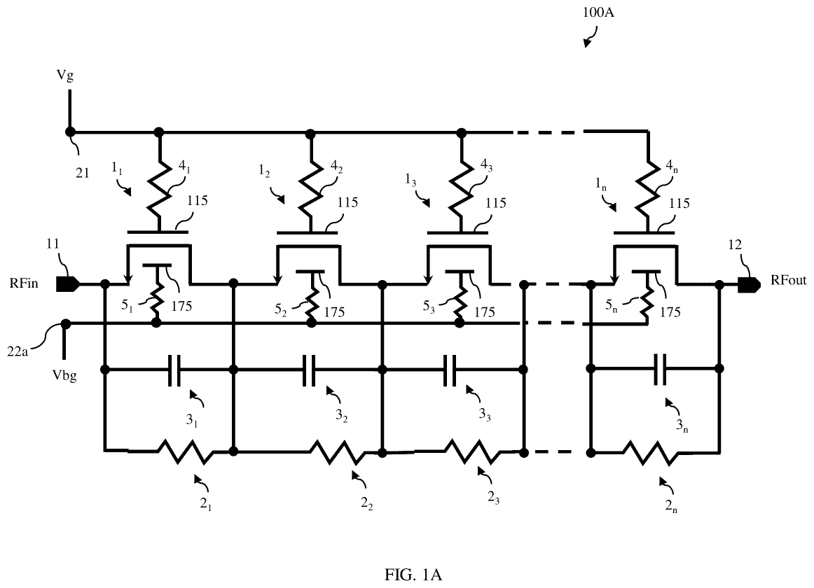

FIGS. 1A and 1B are schematic diagrams illustrating RF switch circuits 100A and 100B, respectively, each including series-connected transistors 1₁-1ₙ connected between an input terminal 11 that receives an RF input signal (RFin) and an output terminal 12 that outputs an RF output signal (RFout). Series-connected transistors 1₁-1ₙ are referred to herein as a stack of transistors or a transistor stack with transistor 1₁ being the top or first transistor in the stack connected to the input terminal 1₁ and transistor In being the bottom or last transistor in the stack connected to the output terminal 12. For purposes of illustration, a stack of four transistors (i.e., n=4) are shown in the circuit diagrams. However, it should be understood that the figures are not intended to be limiting. Those skilled in the art will recognize that RF switch circuit performance can be improved by increasing the number (n) of transistors in the stack.

Transistors 1₁-1ₙ can be field effect transistors (FETs). In some embodiments, transistors 1₁-1ₙ can be N-channel FETs (NFETs). In this case, top NFET 1₁ has a source region connected to input terminal 1₁ and bottom NFET 1₁ has a drain region connected to output terminal 12. Transistors 1₁-1ₙ can be fully depleted semiconductor-on-insulator transistors (e.g., fully depleted silicon-on-insulator (FDSOI) transistors) (e.g., as shown in the RF switch circuit 100A of FIG. 1A). Alternatively, transistors 1₁-1ₙ can be partially depleted semiconductor-on-insulator transistors (e.g., partially depleted silicon-on-insulator (PDSOI) transistors) (e.g., as shown in the RF switch circuit 100B of FIG. 1B). Alternatively, transistors 1₁-1ₙ could be implemented in any other suitable processing technology.

In any case, each transistor 1₁-1ₙ can have primary gates 115 (also referred to herein as front gates), respectively. Primary gates 115 can be connected via resistive elements 4₁-4ₙ to a common primary gate node 21. Common primary gate node 21 can be connected to receive a primary gate voltage (Vg) that controls the on/off state of the RF switch.

Transistors 1₁-1ₙ can further include additional components that are biasable to adjust threshold voltage (VT). For example, as mentioned above, in RF switch circuit 100A of FIG. 1A, transistors 1₁-1ₙ are fully depleted semiconductor-on-insulator (FDSOI) transistors. Such transistors can include secondary gates 175 (also referred to herein as back gates), respectively. Secondary gates 175 can be connected via resistive elements 5₁-5ₙ to a common secondary gate node 22a. Common secondary gate node 22a can be connected to receive a secondary gate voltage (also referred to herein as a back gate voltage (Vbg)) for back biasing the transistors 1₁-1ₙ to adjust VT. Alternatively, in RF switch circuit 100B of FIG. 1B, transistors 1₁-1ₙ are partially depleted semiconductor-on-insulator transistors. Such transistors have biasable body regions 114 (as opposed to back gates), which are connected via resistive elements 5₁-5ₙ to a common body biasing node 22b. Common body biasing node 22b can be connected to receive a body bias voltage (Vb) for biasing the body regions 114 of the transistors 1₁-1ₙ to adjust VT.

RF switch circuits 100A and 100B can each further include resistors 2₁-2ₙ connected in parallel with transistors 1₁-1ₙ. For example, middle of the line (MOL) contacts to source and drain regions of the transistors 1₁-1ₙ can be connected via resistors 2₁-2ₙ in back end of the line (BEOL) metal levels. Alternatively, any other suitable configurations of resistors connected in parallel to the transistors could be employed.

RF switch circuits 100A and 100B can each further include capacitive elements 3₁-3ₙ connected in parallel with transistors 1₁-1ₙ. Those skilled in the art will recognize that the required capacitance values for capacitance elements 3₁-3ₙ, respectively, can increase from a relatively low capacitance value for capacitive element 3ₙ (which is connected to the bottom transistor In in the stack at the output terminal 12) to a relatively high capacitance value for capacitive element 3₁ (which is connected to the top transistor 1₁ in the stack at the input terminal 1₁). Capacitance elements 3₁-3ₙ can include internal parasitic capacitances and, as needed, compensation capacitors such as BEOL metal-insulator-metal capacitors (MIMCAPs).

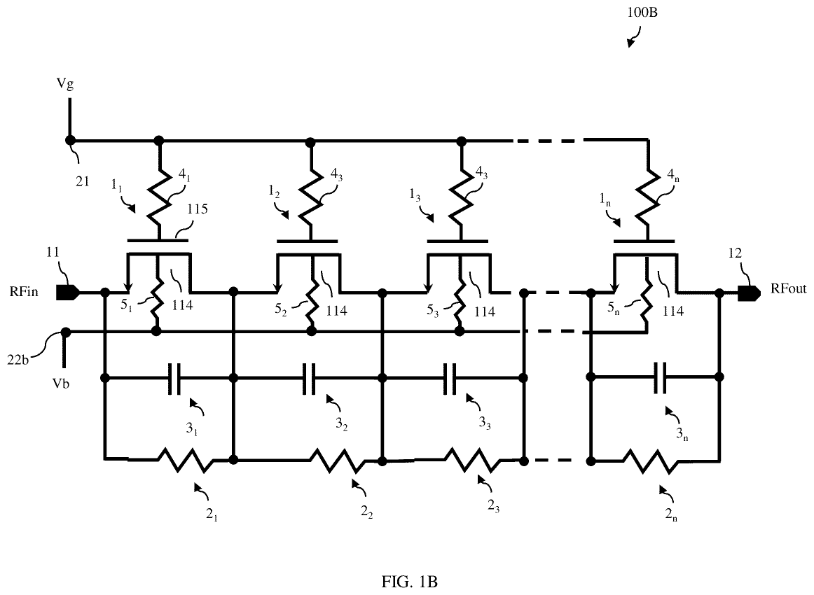

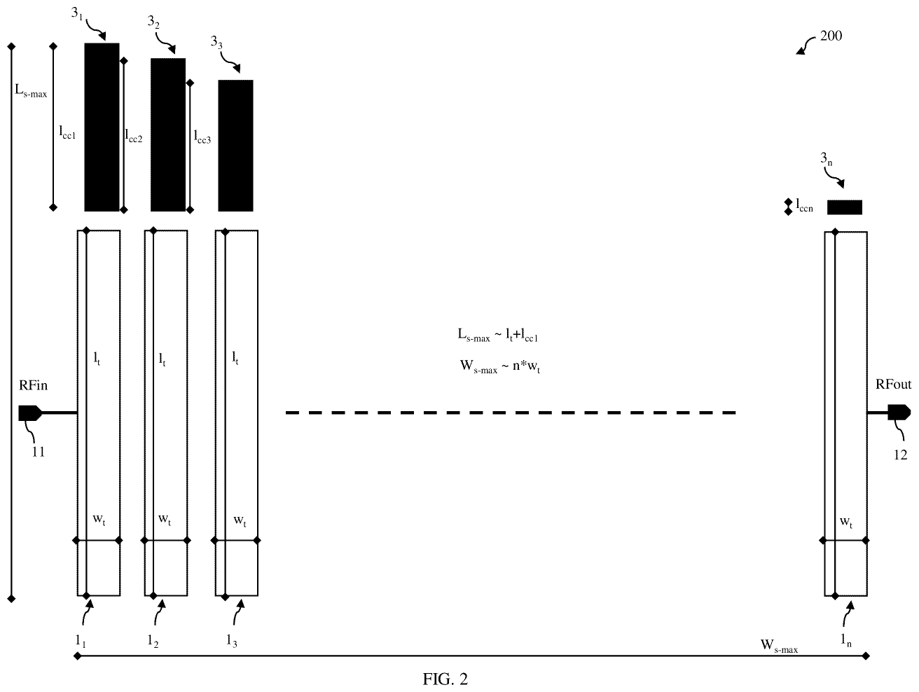

FIG. 2 is a layout diagram illustrating one example of an RF switch structure 200, which has the same circuit configuration as described above and illustrated in either the RF switch circuit 100A of FIG. 1A or the RF switch circuit 100B of FIG. 1B and in which transistors 1₁-1ₙ are all essentially identical multi-finger FETs (e.g., as illustrated in FIG. 3).

Specifically, referring to FIGS. 2 and 3 in combination, each transistor 1₁-1ₙ in RF switch structure 200 is a multi-finger FET having the same transistor layout width (wₜ) (also referred to herein as the transistor cell width) and the same transistor layout length (lₜ) (also referred to herein as the transistor cell height). Each transistor 1₁-1ₙ includes an active device region in a semiconductor layer. The active device region is laterally surrounded by isolation regions (e.g., shallow trench isolation (STI) regions). The active device region includes alternating source and drain regions 311 and 312 and a channel region positioned laterally between each source region 311 and drain region 312. All source regions 311 are electrically connected by a source interconnect 321. Source interconnect 321 can include: BEOL source wires 341, which are parallel to each other and which extend over source regions 311; MOL source contacts 351, which extend essentially vertically between source wires 341 and source regions 311 below; and a BEOL source connecting wire 331, which is perpendicular to and further electrically connected to (e.g., in contact with or otherwise electrically connected to) BEOL source wires 341 on one side of the multi-finger FET. All drain regions 312 are electrically connected by a drain interconnect 322. Drain interconnect 322 can include: BEOL drain wires 342, which are parallel to each other and which extend over drain regions 312; MOL drain contacts 352, which extend essentially vertically between drain wires 342 and drain regions 313 below; and a BEOL drain connecting wire 332, which is perpendicular to and further electrically connected to (e.g., in contact with or otherwise electrically connected to) BEOL drain wires 342. The source and drain interconnects 321 and 322 are considered fully interdigitated because source wires 341 (and source contacts) extend essentially the full length of source regions 311 and drain wires 342 (and drain contacts) similarly extend essentially the full length of drain regions 312.

In RF switch structure 200, each transistor 1₁-1ₙ includes a primary gate structure 315 (also referred to herein as a front gate structure). Primary gate structure 315 includes parallel gates 335 (also referred herein as gate fingers) above the active device region traversing the channel regions, respectively, and at least one connecting gate 325 above an isolation region perpendicular to and in contact with each of the parallel gates 335. It should be noted that the number of gate fingers is the same across all transistors 1₁-1ₙ in the transistor layout 200. Those skilled in the art will recognize that the effective channel length and thereby the drive current of a multi-finger FET depends upon the number of gate fingers. Thus, the effective channel length and drive current are also the same across all transistors 1₁-1ₙ in the transistor layout 200.

In RF switch structure 200, each transistor 1₁-1ₙ includes over-gate gaps 345. For purposes of this disclosure, an over-gate gap refers to a gap (i.e., a cavity or void) filled with air (i.e., an air-gap), filled with some other gas, or under vacuum. Such over-gate gaps 345 are within interlayer dielectric (ILD) material above at least the gate fingers 335 for reducing source-drain capacitance (Csd). Spacing between each source contact 351 or drain contact 352 and the adjacent gate fingers 335 (referred to herein as gate-to-source/drain contact spacing (d)) the same across all transistors 1₁-1ₙ in the transistor layout 200. Scaling of d is limited because of the presence of the over-gate gaps 345.

In RF switch structure 200, each transistor 1₁-1ₙ includes contacts 355 that land on the primary gate structure 315 (e.g., on the connecting gate structure 325 above the isolation region). Gate contacts 355 can be electrically connected to a common primary gate node (not shown) for receiving Vg. If transistors 1₁-1ₙ are fully-depleted semiconductor-on-insulator transistors (e.g., as in RF switch circuit 100A of FIG. 1A), then they can include well taps 319a. Such well taps 319a can be electrically connected (e.g., via contacts landing thereon) to a common secondary gate node for receiving Vbg, can extend to well region(s) aligned below transistors 1₁-1ₙ, and can provide a means for back biasing transistors 1₁-1ₙ. If transistors 1₁-1ₙ are partially-depleted semiconductor-on-insulator transistors (e.g., as in RF switch circuit 100B of FIG. 1B), then they can include body contact regions 319b. Such body contact regions 319b can be in contact with transistor body regions and further electrically connected (e.g., via contacts landing thereon) to a common body biasing node for receiving a body bias voltage (Vb).

RF switch structure 200 can further include compensation capacitors 3₁-3ₙ (e.g., MIMCAPs), which are electrically connected to and aligned with the transistors 1₁-1ₙ, respectively. As illustrated in FIG. 2, compensation capacitors 3₁-3ₙ vary in size across RF switch structure 200. This is to accommodate relatively high power RF input signals (i.e., a high Pmax). Closer to input terminal 1₁ the compensation capacitors have larger capacitance values and, thus, are larger in size than the compensation capacitors closer to the output terminal 12. For example, compensation capacitor layout lengths l_{cc1}-l_{ccn} can decrease progressively from the largest compensation capacitor 3₁ connected to the top transistor 1₁ to the smallest compensation capacitor 3ₙ connected to the bottom transistor 1ₙ.

Thus, in RF switch structure 200, the maximum RF switch layout length (Lₛ₋ₘₐₓ) (also referred to the RF switch cell height) is approximately equal to the sum of lₜ and l_{cc1} and can be over 350 μm. Additionally, the maximum RF switch layout width (Wₛ₋ₘₐₓ) (also referred to herein as the RF switch cell width) is approximately equal to n*wₜ and can be over 250 μm. Unfortunately, Lₛ₋ₘₐₓ is relatively large due to the size of the high capacitance compensation capacitors close to the input terminal 12 and, thus, the total amount of chip area consumed by RF switch configuration 200 may be impractically large.

In view of the foregoing, disclosed herein are embodiments of a radio frequency (RF) switch structure, which has a circuit configuration as described generally above and illustrated in the RF switch circuit 100A of FIG. 1A or 100B of FIG. 1B. However, the physical design of the RF switch structure has been optimized so that it consumes less chip area and has approximately the same or improved high power performance (e.g., as compared to the RF switch structure 200 of FIG. 2). More particularly, in the disclosed embodiment, the RF switch structure can include an input terminal for receiving a high power RF input signal, an output terminal for outputting an RF output signal, and series-connected transistors (i.e., a transistor stack) between the input terminal and the output terminal. Different sections of the transistor stack can have different transistor configurations for achieving different parasitic capacitances. The different sections can include, for example, a first section connected to the input terminal and a second section connected between the first section and the output terminal. The second section can have over-gate gaps, as discussed in greater detail below, for reduced source-to-drain capacitance, whereas the first section can be devoid of such over-gate gaps. Optionally, gate-to-source/drain contact spacing can be larger in the second section than in the first section. Optionally, transistor layout length can be longer in the second section than in the first section. Optionally, source and drain interconnect interdigitation can be less in the second section than in the first section. Optionally, sub-sections of the series-connected transistors within the first section and/or within the second section can also have different configurations, as discussed in greater detail below. As a result of the different transistor configurations, the numbers and sizes of compensation capacitors coupled to the transistors within the RF switch structure can be reduced (e.g., only relatively small compensation capacitors may need to be coupled to transistors in the first section and the need for compensation capacitors coupled to transistors in the second section may be completely eliminated).

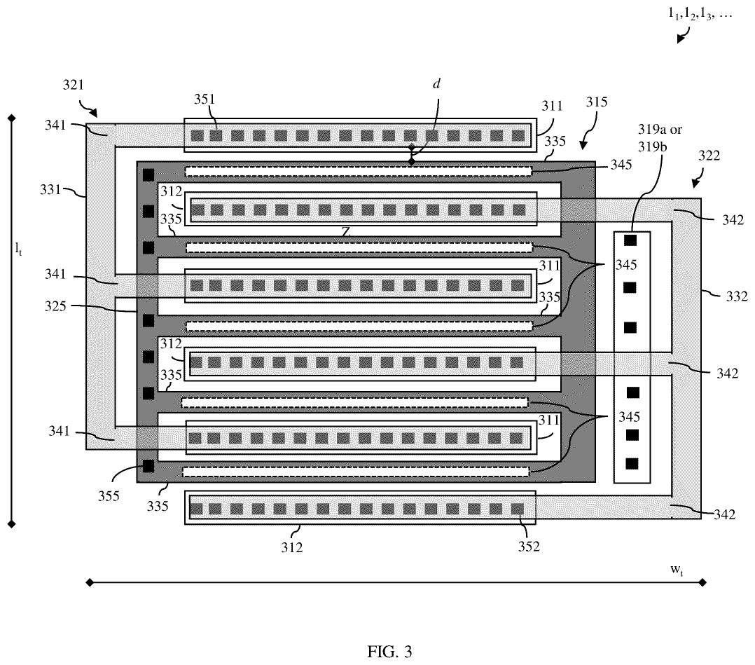

FIG. 4 is a layout diagram illustrating disclosed embodiments of a compact, high power, RF switch structure 400 (e.g., an RF switch tuner). RF switch structure 400 includes essentially the same components as RF switch circuit 100A of FIG. 1A or of RF switch circuit 100B of FIG. 1B, as described in detail above. That is, RF switch structure 400 includes: an input terminal 1₁; an output terminal 12; a stack of transistors 1₁-1ₙ connected between input terminal 1₁ and output terminal 12; resistors 2₁-2ₙ and capacitive elements 3₁-3ₙ connected in parallel with transistors 1₁-1ₙ; resistive elements 4₁-4ₙ connecting primary gates of transistors 1₁-lₙ to a common primary gate node 21 for receiving Vg; and resistive elements 5₁-5ₙ connecting either secondary gates to a common secondary gate node 22a for receiving Vbg or body regions to a common body biasing node 22b for receiving Vb (depending upon whether the transistors are fully depleted or partially depleted semiconductor-on-insulator transistors). To avoid clutter in the figures and to allow the reader to focus on the salient aspects of the disclosed embodiments some of the RF switch circuit features have been omitted from the layout diagram of FIG. 4.

Referring to FIG. 4, in RF switch structure 400 transistors 1₁-1ₙ can be multi-finger transistors. The multi-finger transistors can be, for example, NFETs. Transistors 1₁-1ₙ can be laid out (i.e., arranged) in a line and connected in series between the input terminal 1₁ and the output terminal 12. Additionally, transistors 1₁-1ₙ can be organized into at least two sections with groups of transistors in the different sections, respectively, having different structural configurations. Optionally, any or all sections can also be organized into sub-sections with sub-groups of transistors in the different sub-sections, respectively, also having different structural configurations.

For purposes of illustrated, RF switch structure 400 is shown in the layout diagram of FIG. 4 as having two sections: a first section (hereinafter referred to as section A) and a second section (hereinafter referred to as section B). Additionally, section A is shown as having three sub-sections (sub-sections A1, A2, and A3) and section B is shown as having two sub-sections (sub-sections B1 and B2). It should be understood that the layout diagram of FIG. 4 is provided for illustration purposes and is not intended to be limiting. Alternatively, RF switch structure 400 could include more than two sections, one or more sections with more than 2 or 3 sub-sections, and/or one or more sections with no sub-sections (i.e., one or more sections where all transistors therein have the same configuration). Furthermore, each section or sub-section thereof can include any number of one or more of the transistors.

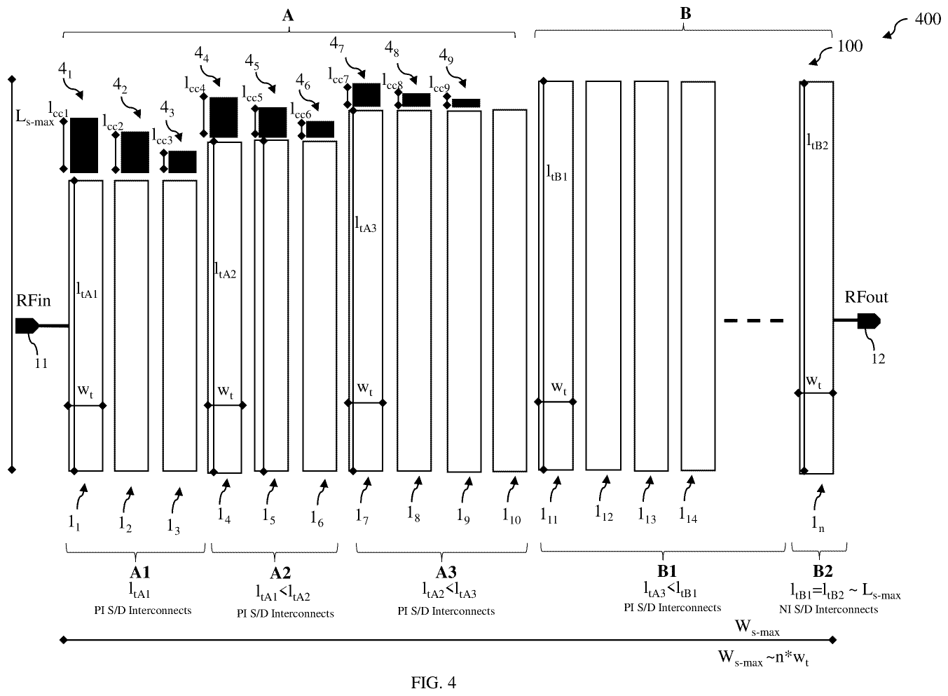

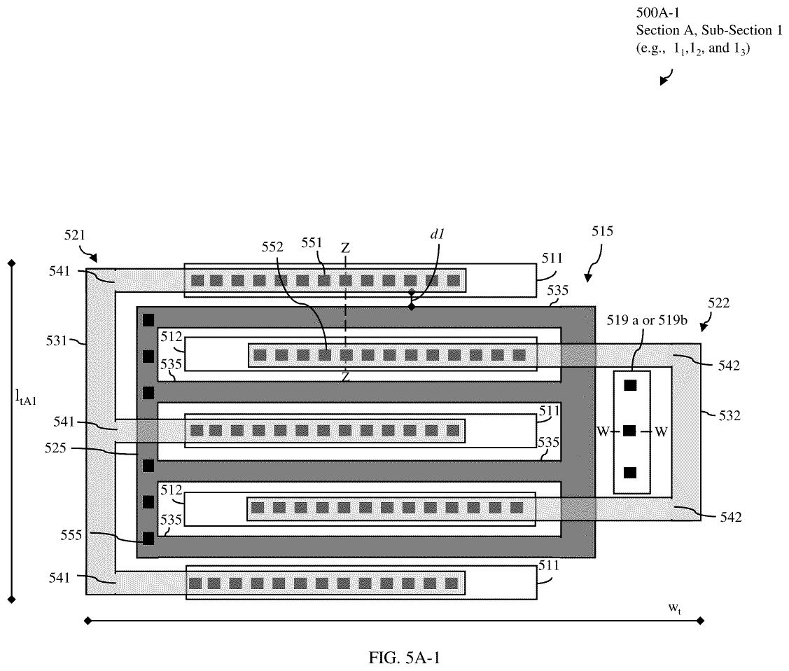

FIG. 5A-1 is a layout diagram 500A-1 illustrating in greater detail an example of a multi-finger transistor structure that can be employed for all transistors within sub-section A1 of section A (e.g., transistors 1₁-1₃). FIG. 5A-2 is a layout diagram 500A-2 illustrating in greater detail an example of another multi-finger transistor structure that can be employed for all transistors within sub-section A2 of section A (e.g., transistors 1₄-1₆). FIG. 5A-3 is a layout diagram 500A-3 illustrating in greater detail an example of yet another multi-finger transistor structure that can be employed for all transistors within sub-section A3 of section A (e.g., see transistors 1₇-1₁₀). FIG. 5B-1 is a layout diagram 500B-1 illustrating in greater detail an example of yet another multi-finger transistor structure that can be employed for all within sub-section B1 of section B (e.g., transistors 1₁₁-1ₙ₋₁). FIG. 5B-2 is a layout diagram 500B-2 illustrating in greater detail an example of yet another multi-finger transistor structure that can be employed for any transistors within sub-section B2 of section B (e.g., transistor 1ₙ). Again, to avoid clutter in the figures and to allow the reader to focus on the salient aspects of the disclosed embodiments some transistor features have been omitted from transistor layout diagrams 500A-1 to 500B-2 of FIGS. 5A-1 to 5B-2.

Referring to FIG. 4 in combination with FIGS. 5A-1 to 5B-2, in RF switch structure 400, each transistor 1₁-1ₙ can have an active device region defined in a semiconductor layer by an isolation region (e.g., a shallow trench isolation (STI) region). Each transistor 1₁-1ₙ can further have, within the active device region, alternating source and drain regions 511-512 and channel regions 513 positioned laterally between each source and drain region pair. All source regions 511 in a given transistor can be electrically connected by a source interconnect 521. Source interconnect 521 can include: BEOL source wires 541, which are parallel to each other and which extend partially over source regions 511 (as discussed in greater detail below); MOL source contacts 551, which extend essentially vertically between source wires 541 and source regions 511 below; and a BEOL source connecting wire 531, which is perpendicular to and further electrically connected to (e.g., in contact with or otherwise electrically connected to) BEOL source wires 541 on one side of the transistor. Additionally, all drain regions 512 can be electrically connected by a drain interconnect 522. Drain interconnect 522 can include: BEOL drain wires 542, which are parallel to each other and which extend partially over drain regions 512 (as discussed in greater detail below); MOL drain contacts 552, which extend essentially vertically between drain wires 542 and drain regions 512 below; and a BEOL drain connecting wire 532, which is perpendicular to and further electrically connected to (e.g., in contact with or otherwise electrically connected to) BEOL drain wires 342.

Each transistor 1₁-1ₙ can further include a primary gate structure 515 (also referred to herein as a front gate structure). Primary gate structure 515 can include multiple parallel gates 535 (referred to as gate fingers) on the semiconductor layer traversing the channel regions, respectively. Each primary gate structure 515 can further include least one connecting gate structure 525. The connecting gate structure 525 can, for example, be above the isolation region, perpendicular to and in contact with each of the gate fingers 535. In this case, the connecting gate structure 525 could be formed concurrently with the gate fingers 535 so as to have essentially the same material composition. Alternatively, the connecting gate structure 525 could be a discrete structure (e.g., a conductive strap) electrically connected to the gate fingers 535 (e.g., via contacts). In any case, gate contacts 555 can land on the gate structure 515 (e.g., on the connecting gate structure 525) and can be electrically connected to a common primary gate node (not shown) for receiving Vg.

As mentioned above, transistors in different sections can have different structural configurations. Furthermore, transistors in different sub-sections of the same section can have different structural configurations. Example differences between transistors in section A and section B, between transistors in sub-sections A1, A2 and A3 of section A and/or between transistors in sub-sections B1 and B2 of section B can include, but are not limited to, any one or more of the following.

In RF switch structure 400, all transistors 1₁₁-1ₙ in section B can have over-gate gaps 545, whereas all transistors 1₁-1₁₀ in section A can be devoid of such over-gate gaps. That is, as illustrated in transistor layout diagrams 500B-1 of FIG. 5B-1 and 500B-2 of FIG. 5B-2, gate structures 515 of transistors 1₁₁-1ₙ in section B (including in sub-sections B1 and B2) can include over-gate gaps 545. As mentioned above, an over-gate gap refers to a gap (i.e., a cavity or void) filled with air (i.e., an air-gap), filled with some other gas, or under vacuum. Such over-gate gaps 545 are encapsulated within ILD material at least above gate fingers 535 and are included to reduce source-drain capacitance (Csd). As illustrated in transistor layout diagrams 500A-1 of FIG. 5A-1, 500A-2 of FIG. 5A-2, and 500A-3 of FIG. 5A-3, gate structures 515 of transistors 1₁-1₁₀ in section A (including in sub-sections A1, A2, and A3) do not include such over-gate gaps and instead ILD material fills spaces above gate fingers 535.

In RF switch structure 400, all transistors 1₁₁-1ₙ in section B can have larger gate-to-source/drain contact spacings than transistors 1₁-1₁₀ in section A. For example, as illustrated in transistor layout diagrams 500A-1 of FIG. 5A-1, 500A-2 of FIG. 5A-2, and 500A-3 of FIG. 5A-3, all transistors 1₁-1₁₀ in section A (including in sub-sections A1, A2, and A3) can have a first gate-to-source/drain contact spacing (d1). As illustrated in transistor layout diagrams 500B-1 of FIG. 5B-1 and 500B-2 of FIG. 5B-2, all transistors 1₁₁-1ₙ in section B (including in sub-sections B1 and B2) can have a second gate-to-source/drain contact spacing (d2) that is different from d1 and, particularly, that is greater than d1. It should be noted that due to critical dimension specifications related over-gate gaps 545, d2 in transistors 1₁₁-1ₙ in section B will typically need to be relatively large. However, since transistors 1₁-1₁₀ in section A are devoid of such over-gate gaps, d1 can be relatively small.

In RF switch structure 400, all transistors 1₁₁-1ₙ in section B can have longer transistor layout lengths (lₜ) than the transistors 1₁-1₁₀ in section A. Furthermore, while all transistor layout lengths of transistors 1₁₁-1ₙ in section B (including in sub-sections B1 and B2) can be essentially the same, transistor layout lengths of transistors in different sub-sections of section A can be different. For example, as illustrated in transistor layout diagrams 500A-1 of FIG. 5A-1, 500A-2 of FIG. 5A-2, and 500A-3 of FIG. 5A-3, transistor layout lengths can increase progressively from sub-section A1 to sub-section A3. For example, all transistors 1₁-1₃ in sub-section A1 can have the shortest transistor layout length l_{tA1}, all transistors 1₄-1₆ in sub-section A2 can have a transistor layout length l_{tA2} that is greater than l_{tA1}, and all transistors 1₇-1₁₀ in sub-section A3 can have a transistor layout length l_{tA3} that is greater than l_{tA2}. Furthermore, as illustrated in the transistor layout diagrams 500B-1 of FIG. 5B-1 and 500B-2 of FIG. 5B-2, all transistors 1₁₁-1ₙ₋₁ in sub-section B1 can have a transistor layout length l_{tB1} that is longer than l_{tA3} and transistor In within sub-section B2 can have a transistor layout length l_{tB2} that is essentially equal to l_{tB1} (i.e., the longest transistor layout length). In one example embodiment, l_{tA1} could be between 170 and 180 μm and l_{tB2} could be between than 220 and 230 μm. Increasing transistor layout lengths, as discussed above, can be achieved, for example, by adding gate fingers (and additional source/drain regions) to the transistors. Thus, as illustrated in FIGS. 500A-1 to 500B-2, all transistors 1₁₁-1ₙ in section B can have more gate fingers 535 than the transistors 1₁-1₁₀ in section A. Furthermore, while transistors 1₁₁-1ₙ in section B (including with sub-sections B1 and B2) have the same number of gate fingers, the number of gate fingers within transistors in different sub-sections of section A can be different. For example, transistors 1₇-1₁₀ in sub-section A3 can have fewer gate fingers than transistors 1₁₁-1ₙ in section B, transistors 1₄-1₆ in sub-section A2 can have fewer gate fingers than transistors 1₇-1₁₀ in sub-section A3, and transistors 1₁-1₃ in sub-section A1 can have fewer gate fingers than transistors 1₄-1₆ in sub-section A2. Those skilled in the art will recognize that variations in the number of gate fingers results not only in variations in the transistor layout lengths but also variations in effective channel length and thereby drive current. Thus, transistors 1₁₁-1ₙ in section B will have a greater effective channel length and greater drive current than transistors 1₇-1₁₀ in sub-section A3, transistors 1₇-1₁₀ in sub-section A3 will have a greater effective channel length and greater drive current than transistors 1₄-1₆ in sub-section A2, and so on.

It should be noted that transistor layout diagrams 500A-1 to 500B-2 of FIGS. 5A-1 to 5B-2 are provided for illustration purposes and are not intended to be limiting. For example, while these layout diagrams show transistors with different numbers of gate fingers, the numbers of gate fingers in the transistor in each transistor layout and the differences in the numbers of gate fingers between the different transistor layouts are not intended to be limiting. Those skilled in the art will recognize that an RF switch structure (e.g., RF switch tuner) could include many more gate fingers 535 than illustrated (e.g., 10s, 100s, etc. of gate fingers). Additionally, it should be noted that, as illustrated, interdigitation of the source and drain interconnects 521 and 522 across the RF switch 400 can be varied. In the disclosed embodiments, transistors proximal to input terminal 11 can have a greater amount of interdigitation of the source and drain interconnects 521 and 522, then transistors proximal to output terminal 12. By reducing the amount of interdigitation of the source and drain interconnects 521 and 522, Csd can be reduced.

For example, referring to FIGS. 5A-1 to 5B-1, transistors 1₁-1₁₀ in section A and transistors 1₁₁-1ₙ₋₁ in sub-section B1 of section B can have partially interdigitated source and drain interconnects 521 and 522 (as opposed to fully interdigitated source and drain regions as shown in FIG. 3 and described above). Specifically, in the multi-finger FETs shown in FIGS. 5A-1 to 5B-1, source wires 541 (and source contacts) do not extend the full length of source regions 511 and drain wires 542 (and drain contacts) similarly do not extend essentially the full length of drain regions 512. Instead, source wires 541 (and source contacts) extend over half but less than the full length of source regions 511 and drain wires 542 (and drain contacts) similarly extend over half but less than the full length of drain regions 512. Thus, the source and drain interconnects 521 and 522 of these transistors are only considered to be partially interdigitated to reduce Csd. Furthermore, referring to FIG. 5B-2, transistor 1, in sub-section B2 of section B (i.e., the bottom transistor in the stack) can have non-interdigitated source and drain interconnects 521 and 522. That is, in this case source wires 541 (and source contacts) extend no more than half the full length of source regions 511 and drain wires 542 (and drain contacts) similarly extend no more than half the full length of drain regions 512. Thus, the source and drain interconnects 521 and 522 of in the bottom transistor 1ₙ do not overlap at all and are considered non-interdigitated such that Csd is reduced even further.

As mentioned above, in the disclosed embodiments, transistors 1₁-1ₙ of the RF switch structure 400 can be either fully depleted semiconductor-on-insulator transistors (e.g., to achieve the RF switch circuit of 100A of FIG. 1A) or partially depleted semiconductor-on-insulator transistors (e.g., to achieve the RF switch circuit 100B of FIG. 1B). The following is a more detailed discussion of such fully depleted and partially depleted semiconductor-on-insulator transistor structures.

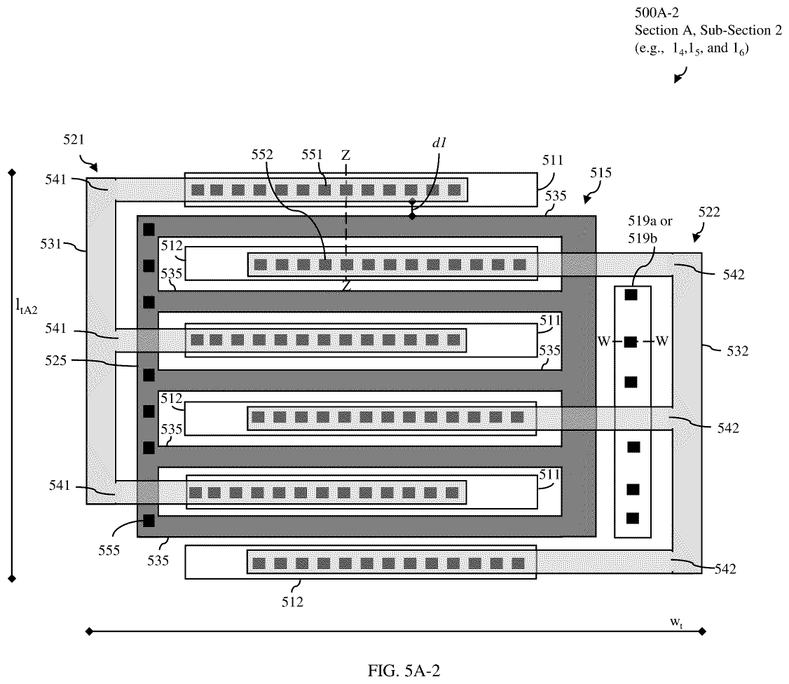

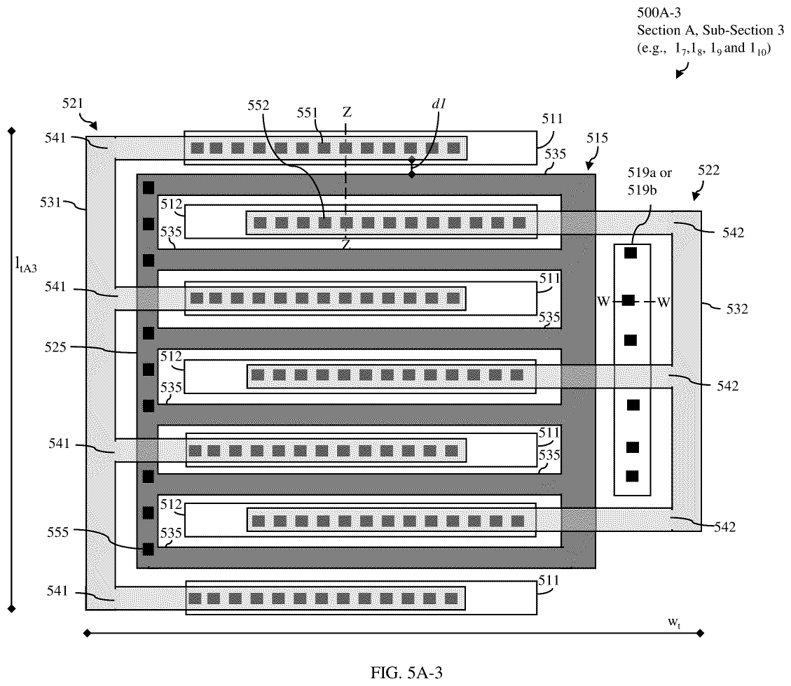

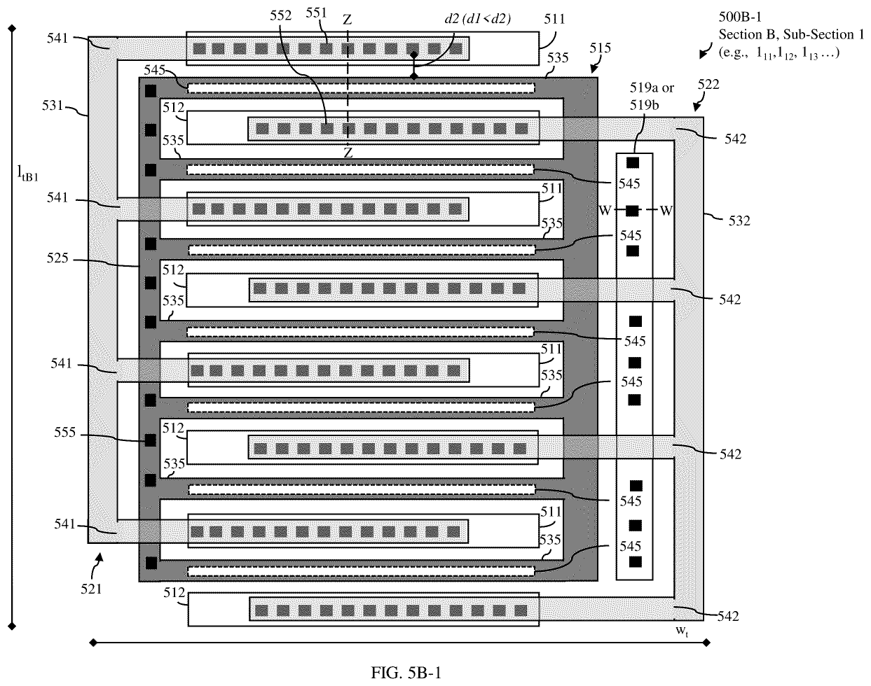

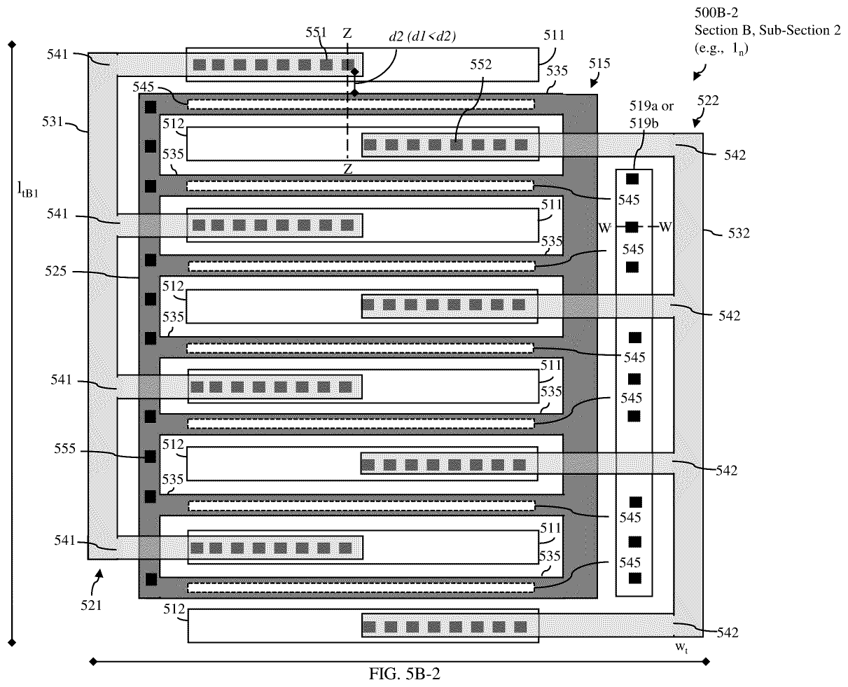

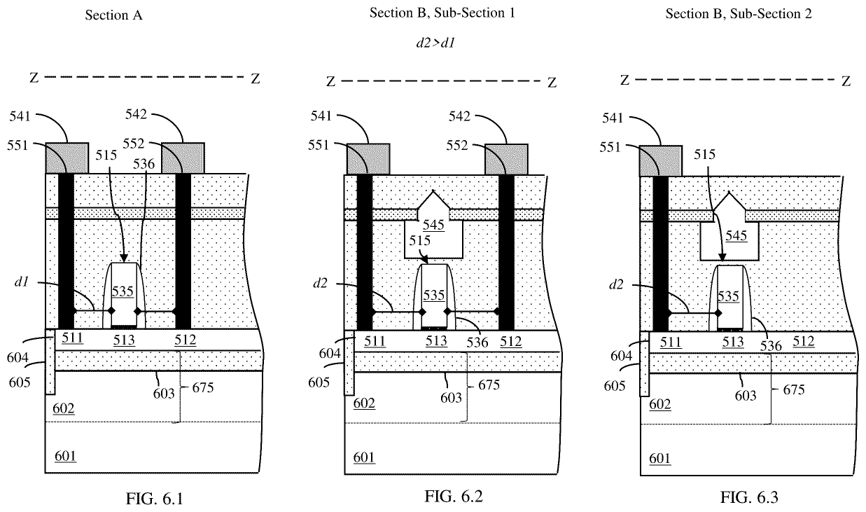

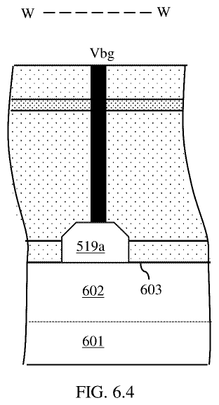

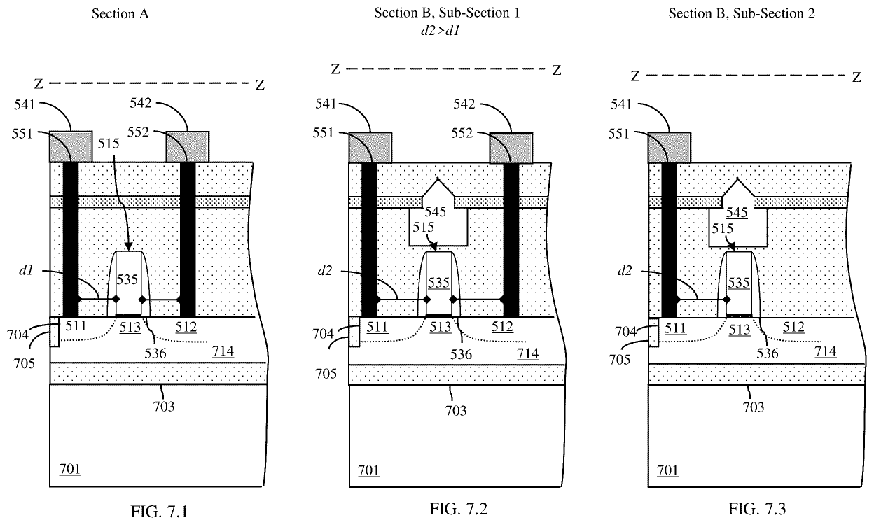

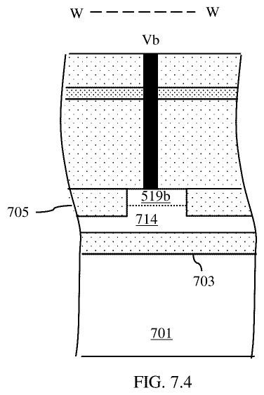

Specifically, FIGS. 6.1-6.3 illustrate examples of a vertical cross-section ZZ approximately midline through a single gate finger 535 of an FDSOI multi-finger FET as laid out in FIGS. 5A-1 to 5A-3 (see FIG. 6.1), as laid out in FIG. 5B-1 (see FIG. 6.2), and as laid out in FIG. 5B-2 (see FIG. 6.3). FIG. 6.4 illustrates a vertical cross-section WW through a well tap 519a to well region 602 in below an FDSOI multi-finger FET. FIGS. 7.1-7.3 illustrate examples of a vertical cross-section ZZ approximately midline through a single gate finger 535 of a PDSOI multi-finger FET as laid out in FIGS. 5A-1 to 5A-3 (see FIG. 7.1), as laid out in FIG. 5B-1 (see FIG. 7.2), and as laid out in FIG. 5B-2 (see FIG. 73). FIG. 7.4 illustrates a vertical cross-section WW through a body contact region 519b to a body region 714 of such a PDSOI multi-finger FET.

Referring to FIGS. 6.1-6.4 and FIGS. 7.1-7.4 in combination with FIGS. 4 and 5A-1 to 5B-2, RF switch structure 400 can include a semiconductor substrate 601, 701.

Semiconductor substrate 601, 701 can be, for example, a monocrystalline silicon substrate or a substrate of any other suitable monocrystalline semiconductor material (e.g., silicon germanium, etc.). In some embodiments, semiconductor substrate 601, 701 can be doped so as to have P-type conductivity at a relatively low conductivity level (e.g., so as to be a P-semiconductor substrate).

RF switch structure 400 can further include an insulator layer 603, 703 above and immediately adjacent to the top surface of semiconductor substrate 601, 701. Insulator layer 603, 703 can be, for example, a thin oxide layer (also referred to herein as a buried oxide (BOX) layer), such as a silicon dioxide layer. Alternatively, insulator layer 603, 703 can be a relatively thin layer of any other suitable insulator material.

RF switch structure 400 can further include a semiconductor layer 604, 704 above and immediately adjacent to the top surface of insulator layer 603, 703. Semiconductor layer 604, 704 can be, for example, a monocrystalline silicon layer or a layer of any other suitable monocrystalline semiconductor material (e.g., monocrystalline silicon germanium, etc.). Those skilled in the art will recognize that for an FDSOI structure semiconductor layer 604 will be relatively thin (e.g., between 3-20 nm) so that transistors formed thereon are fully depleted.

RF switch structure 400 can further include isolation regions 605, 705 (e.g., shallow trench isolation (STI) regions) that define active device regions for transistors 1₁-1ₙ. Isolation regions 605, 705 can include trenches, which are filled with one or more layers of isolation material (e.g., silicon dioxide, silicon nitride, silicon oxynitride, etc.). Such isolation regions 605, 705 can laterally surround and thereby define the boundaries of the active device regions for transistors 1₁-1ₙ. Those skilled in the art will recognize that the depths of such isolation regions may vary depending upon whether the transistors are fully depleted or partially depleted. For example, as shown in FIGS. 6.1-6.4, isolation regions 605 can extend through semiconductor layer 604 and, optionally, through insulator layer 603 into the semiconductor substrate 601. However, as shown in FIGS. 7.1-7.4, at least some of isolation regions 705 may optionally extend only partially into the semiconductor layer 704 such that the bottom of the isolation regions and top of insulator layer 703 are separated by some distance (e.g., to facilitate body contacting as discussed in greater detail below). Although not shown in the figures, each active device region can (for example) be essentially rectangular in shape (e.g., when viewed in a horizontal cross-section).

Within RF switch structure 400, each transistor 1₁-1ₙ can be a multi-finger FET. Specifically, each transistor 1₁-1₁₀ can include, within a corresponding active device region, alternating source and drain regions 511 and 512 and channel regions 513 positioned laterally between each pair of adjacent source and drain regions 511 and 512. transistors 1₁-1₁₀ can, for example, be NFETs. That is, source and drain regions 511 and 512 can have N-type conductivity at a relatively high conductivity level (e.g., can be N+ source/drain regions) and each channel region 513 can be either intrinsic (i.e., undoped) or can have P-type conductivity at a relatively low conductivity level (e.g., can be an undoped or P-channel region).

Those skilled in the art will recognize that the depths of the source/drain regions will vary depending upon whether the transistors are fully depleted or partially depleted. For example, as illustrated, in FDSOI, source/drain regions 511-512 can extend from the top surface of the semiconductor layer 604 to the top surface of the insulator layer 603 (as shown in FIGS. 6.1-6.4 and discussed in greater detail below). In a PDSOI multi-finger FET, source/drain regions 511-512 can extend from the top surface of the semiconductor layer 704 down to a depth above the level of the top surface of the insulator layer 703 so that a body region 714 (e.g., with the same type conductivity and conductivity level as the channel region 513) is within the semiconductor layer 704 below the active device region (i.e., below the source, drain and channel regions) and further extending laterally beyond the active device region so that it can be contacted (as shown in FIGS. 7.1-7.4 and discussed in greater detail below).

Optionally, a multi-finger FET can further have raised source and drain regions (not shown) on source and drain regions 511 and 512, respectively. Raised source and drain regions can be epitaxial semiconductor layers grown on the top surface of the semiconductor layer and in situ doped so as to have the same type conductivity as the source and drain regions 511 and 512 below. Optionally, silicide layers can be on top surfaces of source and drain regions 511-512 (or if applicable on top surfaces of raised source and drain regions thereon). Such silicide layers can be, for example, layers of cobalt silicide (CoSi), nickel silicide (NiSi), tungsten silicide (WSi), titanium silicide (TiSi), or any other suitable metal silicide material.

Within RF switch structure 400, each transistor 1₁-1ₙ can include a primary gate structure 515, including a gate finger 535 on each channel region 513. Primary gate structure 515 can also include a connecting gate structure 525 (not shown in FIGS. 6.1-6.4 or FIGS. 7.1-7.4), which is outside the defined boundaries of the active device region (e.g., on an isolation region 605, 705) and which electrically connects all gate fingers 535. Primary gate structure 515 (or at least each gate finger 535 thereof) can include a gate dielectric layer (including one or more layers of gate dielectric material) and a gate conductor layer (including one or more layers of gate conductor material) on the gate dielectric layer. In some embodiments, primary gate structure 515 can be a gate-first high-K metal gate (HKMG) gate structure. The gate-first HKMG structure can include, for example, a gate dielectric layer that includes: an interfacial layer (e.g., an SiO2 layer and/or an SiON layer) and a high-K gate dielectric layer on the interfacial layer. The high-K gate dielectric layer can be a layer of dielectric material with a dielectric constant that is greater than 3.9 including, for example, hafnium (Hf)-based dielectrics, such as hafnium oxide, hafnium silicon oxide, hafnium silicon oxynitride, or hafnium aluminum oxide, or other suitable high-k dielectrics, such as aluminum oxide, tantalum oxide, or zirconium oxide. The gate-first HKMG structure can further include, for example, a gate conductor layer that includes at least: one or more stacked metal layers (e.g., a metal capping layer and an additional metal material layer suitable for dipole formation on the metal capping layer) on the high-K gate dielectric layer and an N-doped polysilicon gate conductor layer on the metal gate conductor layer(s). Alternatively, primary gate structure 515 can be any other suitable type of front gate structure (e.g., a gate first polysilicon gate structure, a replacement metal gate structure, etc.) used, for example, in fully depleted semiconductor-on-insulator (e.g., in FDSOI) processing technology platforms.

Within RF switch structure 400, each transistor 1₁-1ₙ can further include gate sidewall spacers 536 positioned laterally adjacent to sidewalls of the primary gate structure 515, including adjacent to gate fingers 535. Gate sidewall spacers 536 can be made of one or more layers of dielectric material such as silicon dioxide, silicon oxynitride, silicon nitride, or any other suitable gate sidewall spacer material. Various gate sidewall spacer configurations are well known in the art and, thus, a detailed description thereof have been omitted from the specification in order to allow the reader to focus on the salient aspects of the disclosed embodiments.

In embodiments where each transistor 1₁-1ₙ is a fully depleted semiconductor-on-insulator transistor (e.g., as shown in FIGS. 6.1-6.4), each transistor 1₁-1ₙ can further include a secondary gate 675 (also referred to herein as back gate). More specifically, one or more well regions 602 can be within and at the top surface of semiconductor substrate 601 immediately adjacent insulator layer 603 below the transistors. For example, a single well region can be aligned below all transistors. Alternatively, discrete well regions can be aligned below one or more of the transistors. For purposes of this disclosure, a well region refers to a region of semiconductor material doped (e.g., via a dopant implantation process or any other suitable doping process) so as to have a particular conductivity type. Well region 602 can be doped so as to have N-type conductivity (i.e., so as to be an Nwell). Alternatively, well region 602 can be doped so as to have P-type conductivity (i.e., so as to be a Pwell). Those skilled in the art will recognize that one advantage of fully depleted semiconductor-on-insulator (e.g., FDSOI) technology processing platforms is that NFETs and PFETs can be formed on an insulator layer above either an Nwell or a Pwell in order to achieve different types of NFETs or PFETs with different VTs. For example, as discussed above, the multi-finger FETs of the RF switch can be multi-finger NFETs. For super low threshold voltage (SLVT) or low threshold voltage (LVT) devices, the multi-finger NFETs can be on the insulator layer 603 aligned above Nwells. For regular threshold voltage (RVT) or high threshold voltage (HVT) devices, the multi-finger NFETs can be on the insulator layer 603 aligned above Pwells. Whether a multi-finger NFET on an insulator layer above an Nwell is an SLVT or LVT device or whether a multi-finger NFET on an insulator layer above a Pwell is RVT or HVT device will depend upon the design (e.g., device size, etc.) and process specifications (e.g., dopant concentrations, etc.). In any case, the secondary gate 675 of a multi-finger FET can include sections, which include corresponding portions of insulator layer 603 and well region 602 that are aligned below the channel regions opposite the gate fingers.

Concurrent back gate biasing of secondary gates 675 of such transistors can be achieved by concurrently applying a particular Vbg to the well region(s) 602 below the transistors 1₁-1ₙ. In some embodiments, transistors 1₁-1ₙ can be zero back biased (e.g., by applying a Vbg of 0.0V to the well regions). In other embodiments, transistors 1₁-1ₙ could be either forward back biased or reversed back biased. Those skilled in the art will recognize that forward back biasing (FBB) refers to biasing conditions where the particular Vbg reduces the VT of the multi-finger FETs. Reverse back biasing (RBB) refers to biasing conditions where the particular Vbg increases the VT. For NFETs, FBB is achieved using a +Vbg and RBB is achieved using a −Vbg.

In order to facilitate such back biasing (e.g., either zero back biasing, FBB or RBB) of fully depleted semiconductor-on-insulator transistors, well taps 519a can be employed (e.g., as shown in the layout diagrams of FIGS. 5A-1 to 5B-2 and further illustrated in FIG. 6.4 and described below). A well tap refers to a well contact region and, particularly, a means of contacting a well region below a buried insulator layer. Such a well tap 519a can be an epitaxial semiconductor layer grown on the top surface of the semiconductor substrate 601 immediately adjacent to the well region 602 and within an opening in the buried insulator layer 603. Typically, the well tap 519a will have the same type conductivity but at a higher conductivity level than the well region. Additionally, it will be electrically isolated from other transistor components above the buried insulator layer 603. Well taps are well known in the art and, thus, the details thereof have been omitted from this specification in order to allow the reader to focus on the salient aspects of the disclosed embodiments.

In embodiments where each transistor 1₁-1ₙ is a partially depleted semiconductor-on-insulator transistor (e.g., as shown in FIGS. 7.1-7.4), each transistor 1₁-1ₙ can further include a biasable body region 714. As mentioned above, a body region 714 of such a transistor is within the semiconductor layer 704 below and extending laterally beyond the active device region so that it can be contacted. Concurrent body biasing of body regions 714 such transistors can be achieved by concurrently applying a particular Vb to the body regions. In some embodiments, body regions 714 can be zero biased (e.g., by applying a Vb of 0.0V thereto). In other embodiments, where the transistors are NFETs a positive Vb could be employed to reduce VT or a negative Vb can be employed to increase VT.

In order to facilitate such body biasing of partially depleted semiconductor-on-insulator transistors body contact regions 519b can be employed (e.g., as shown in the layout diagrams of FIGS. 5A-1 to 5B-2 and further illustrated in FIG. 7.4 and described below). A body contact region refers to a doped region within and at the top surface of a semiconductor layer immediately adjacent to a portion of a body region of a transistor that extends laterally beyond the active device region of the transistor. Typically, the body contact region 519b will have the same type conductivity but at a higher conductivity level than the body region 714. Additionally, it will be electrically isolated from other transistor components above within the semiconductor layer 704. Body contact regions are well known in the art and, thus, the details thereof have been omitted from this specification in order to allow the reader to focus on the salient aspects of the disclosed embodiments.

In any case, as illustrated in FIGS. 5A-1 to 5B-2 and further illustrated in FIGS. 6.1-6.3 for fully depleted semiconductor-on-insulator transistors and in FIGS. 7.1-7.3 for partially depleted semiconductor-on-insulator transistors, transistors 1₁-1₁₀ in section A are devoid of an over-gate gap and transistors 1₁₁-1ₙ in section B have over-gate gaps 545. Furthermore, first gate-to-source/drain contact spacing (d1) in transistors 1₁-1₁₀ in section A is smaller than second gate-to-source/drain contact spacing (d2) in transistors 1₁₁-1ₙ of section B. Source and drain interconnects 521 and 522 in transistors 1₁-1₁₀ in section A and also in transistors 1₁₁-1ₙ₋₁ in sub-section B1 are partially interdigitated. Thus, in at least some areas of transistors 1₁-1ₙ₋₁ source and drain contacts 551 and 552, which land on source and drain regions 511 and 512 on opposing sides of a gate finger 353, respectively, are in the same vertical plane. However, source and drain interconnects 521 and 522 in bottom transistor 1ₙ in sub-section B2 are not interdigitated. Thus, there are no areas in bottom transistor In where source and drain contacts 551 and 552 land on source and drain regions 511 and 512 on opposing sides of a gate finger 353, respectively, in the same vertical plane. Furthermore, transistor layout widths (wₜ) of the various transistors shown in the transistor layout diagrams 500A-1 to 500B-2 can be essentially the same. That is, wₜ can be equal for all transistors within the RF switch 400 and, particularly, essentially the same in all transistors of all sections A and B and sub-sections thereof.

As a result of the different transistor configurations in the different sections A and B (discussed in detail above), transistors in section A proximal to the input terminal 1₁ have relatively short effective channel lengths as compared to transistors in section B proximal to the output terminal 12 and transistors in section B proximal to the output terminal 12 have reduced Csd as compared to transistors in section A proximal to the input terminal 1₁. Within section A, the effective channel lengths can increase progressively with each sub-section. Within section B, Csd can decrease with each sub-section. Thus, the total number of compensation capacitors (e.g., MIMCAPs) needed in the RF switch 400 is reduced and the sizes of those compensation capacitors is also reduced.

For example, referring again to FIG. 4, RF switch structure 400 can further include compensation capacitors (e.g., MIMCAPs) coupled to transistors in section A only. That is, due to the different structural configurations in sections A and B (and optionally the different structural configurations in the sub-sections thereof), the need for compensation capacitors coupled to transistors 1₁₁-1ₙ in section B can be avoided. Furthermore, such compensation capacitors may not be required for all transistors 1₁-1₁₀ in section A. That is, compensation capacitors may be coupled to only some of transistors 1₁-1₁₀ in section A. Additionally, the compensation capacitors can be relatively small and, within each sub-section of section A, the required capacitance values and thereby the sizes of the compensation capacitors can decrease progressively.

For example, transistors 1₁-1₃ in sub-section A1 can have the same transistor layout length (l_{tA1}) but can require coupling to compensation capacitors 3₁-3₃ with progressively smaller capacitance values. Thus, compensation capacitors 3₁-3₃ can have progressively smaller sizes (e.g., progressively smaller capacitor layout lengths (l_{cc1}-l_{cc3})). Transistors 1₄-1₆ in sub-section A2 can have the same transistor layout length (l_{tA2}) that is greater than l_{tA1} and similarly can require coupling to compensation capacitors 3₄-3₆ with progressively smaller capacitance values. Thus, compensation capacitors 3₄-3₆ can have progressively smaller sizes (e.g., progressively smaller capacitor layout lengths (l_{cc4}-l_{cc6})). It should be noted that l_{cc4}-l_{cc6} could all be smaller than l_{cc3}. Alternatively, as illustrated, there could be some overlap in sizes. For example, l_{cc4} can be smaller than l_{cc1} but larger than at least l_{cc3}. Transistors 1₇-1₁₀ in sub-section A3 can have the same transistor layout length (l_{tA3}) that is greater than l_{tA2} and only some of the transistors (e.g., transistors 1₇-1₉) may require coupling to compensation capacitors 3₇-3₉ with progressively smaller capacitance values. Thus, compensation capacitors 3₇-3₉ can have progressively smaller sizes (e.g., progressively smaller capacitor layout lengths (l_{cc7}-l_{cc9})). l_{cc7}-l_{cc9} could all be smaller than l_{cc6}. Alternatively, there could be some overlap in sizes. For example, l_{cc7} can be smaller than l_{cc4} but larger than at least l_{cc6}, as illustrated.

Given the short transistor layout lengths l_{tA1}-l_{tA3} in sub-sections A1-A3 of section A and further given the short capacitor layout lengths (l_{cc1} to l_{cc9}) of compensation capacitors 3₁-3₉ (with l_{cc1} being the longest), the sum of any transistor layout length plus the capacitor layout length for a compensation capacitor coupled thereto can be equal to or less than the transistor layout length (l_{tB2}) for the bottom transistor 1ₙ. Thus, in the disclosed embodiments, the maximum RF switch layout length (Lₛ₋ₘₐₓ) (also referred to the RF switch cell height) is not greater than the transistor layout length (l_{tB2}) for the bottom transistor 1ₙ. As mentioned above, in one example embodiment l_{tB2} could be between approximately 220 μm and approximately 230 μm and, thus, is significantly less than the 350 μm or higher Lₛ₋ₘₐₓ for the RF switch 200 of FIG. 2. The maximum RF switch layout width (Wₛ₋ₘₐₓ) (also referred to herein as the RF switch cell width) is approximately equal to n*wₜ or essentially the same as Wₛ₋ₘₐₓ for the RF switch 200 of FIG. 2. Thus, the RF switch 400 consumes significantly less chip area.

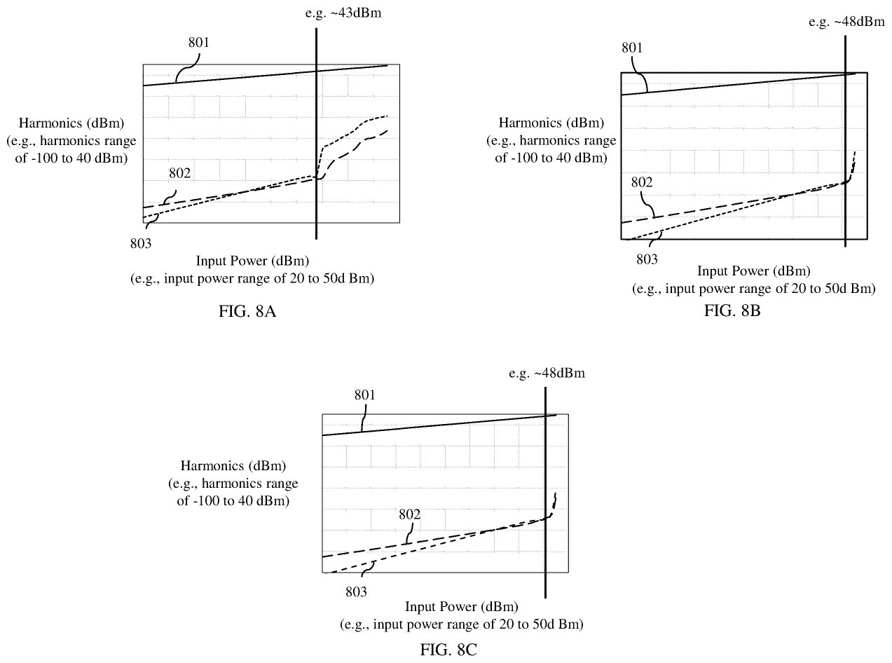

FIGS. 8A-8C are graphs illustrating examples of first order harmonics 801, second order harmonics 802 and third order harmonics 803 exhibited by different RF switch structures including an RF switch structure without any capacitance compensation (see FIG. 8A), an RF switch structure such as the RF switch structure 200 of FIG. 2 with capacitance compensation (see FIG. 8B), and the RF switch structure 400 of FIG. 4 with capacitance compensation (see FIG. 8C). As illustrated, providing capacitance compensation results in an increased Pmax of ˜48 dBm as compared to the Pmax of ˜43 dBm when there is no capacitance compensation. Furthermore, as illustrated, the RF switch structure 400 of FIG. 4 achieves the same or better Pmax than that of the RF switch structure 200 of FIG. 2 while consuming less chip area.

Fully and partially depleted semiconductor-on-insulator implemented structures including various devices, circuit components and other features of an RF switch (including, but not limited to, multi-finger FETs, over-gate gaps incorporated into multi-finger FETs, resistors, and compensation capacitors (e.g., MIMCAPs)) are well known in the art. Thus, the details thereof as well as the process techniques for forming them have been omitted from this specification in order to allow the reader to focus on the salient aspects of the disclosed embodiments (including, but not limited to, reducing the total number and sizes of compensation capacitors required for an RF switch by employing multi-finger FETs with different configurations in different sections and, optionally, in different sub-sections of a transistor stack and, thereby reducing the overall chip area consumed by the RF switch). The different transistor configurations to be used in the different sections and, optionally, in the different sub-sections of each sections can be determined during design through a design process that includes, but is not limited to: establishing design specification for the RF switch including performance specifications (e.g., input power range, Pmax, maximum harmonics level, etc.) and maximum chip area (e.g., Lₛ₋ₘₐₓ and Wₛ₋ₘₐₓ); performing cell selection (e.g., select cells for transistors with different configurations, resistors, compensation capacitors, etc. to be incorporated into the RF switch); performing cell placement to generate a design layout; performing simulations to determine if design specifications have been met; and iteratively repeating these processes until either (a) the design specifications have been met and a final design layout can be released to manufacturing or (b) a decision is made to modify design specifications. In any case, conventional FDSOI processing techniques can be used to form the RF switch according to the novel final design layout.

It should be understood that in the structures and method described above, a semiconductor material refers to a material whose conducting properties can be altered by doping with an impurity. Such semiconductor materials include, for example, silicon-based semiconductor materials (e.g., silicon, silicon germanium, silicon germanium carbide, silicon carbide, etc.) and III-V compound semiconductors (i.e., compounds obtained by combining group III elements, such as aluminum (Al), gallium (Ga), or indium (In), with group V elements, such as nitrogen (N), phosphorous (P), arsenic (As) or antimony (Sb)) (e.g., GaN, InP, GaAs, or GaP). A pure semiconductor material and, more particularly, a semiconductor material that is not doped with an impurity for the purposes of increasing conductivity (i.e., an undoped semiconductor material) is referred to in the art as an intrinsic semiconductor. A semiconductor material that is doped with an impurity for the purposes of increasing conductivity (i.e., a doped semiconductor material) is referred to in the art as an extrinsic semiconductor and will be more conductive than an intrinsic semiconductor made of the same base material. That is, extrinsic silicon will be more conductive than intrinsic silicon; extrinsic silicon germanium will be more conductive than intrinsic silicon germanium; and so on. Furthermore, it should be understood that different impurities (i.e., different dopants) can be used to achieve different conductivity types (e.g., P-type conductivity and N-type conductivity) and that the dopants may vary depending upon the different semiconductor materials used. For example, a silicon-based semiconductor material (e.g., silicon, silicon germanium, etc.) is typically doped with a Group III dopant, such as boron (B) or indium (In), to achieve P-type conductivity, whereas a silicon-based semiconductor material is typically doped with a Group V dopant, such as arsenic (As), phosphorous (P) or antimony (Sb), to achieve N-type conductivity. A gallium nitride (GaN)-based semiconductor material is typically doped with magnesium (Mg) to achieve P-type conductivity and with silicon (Si) or oxygen to achieve N-type conductivity. Those skilled in the art will also recognize that different conductivity levels will depend upon the relative concentration levels of the dopant(s) in a given semiconductor region. Furthermore, when a semiconductor region or layer is described as being at a higher conductivity level than another semiconductor region or layer, it is more conductive (less resistive) than the other semiconductor region or layer; whereas, when a semiconductor region or layer is described as being at a lower conductivity level than another semiconductor region or layer, it is less conductive (more resistive) than that other semiconductor region or layer.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should be understood that the terminology used herein is for the purpose of describing the disclosed structures and methods and is not intended to be limiting. For example, as used herein, the singular forms “a,” “an,” and “the” are intended to include the plural forms as well, unless the context clearly indicates otherwise. Additionally, as used herein, the terms “comprises,” “comprising,” “includes,” and/or “including” specify the presence of stated features, integers, steps, operations, elements, and/or components, but do not preclude the presence or addition of one or more other features, integers, steps, operations, elements, components, and/or groups thereof. Furthermore, as used herein, terms such as “right,” “left,” “vertical,” “horizontal,” “top,” “bottom,” “upper,” “lower,” “under,” “below,” “underlying,” “over,” “overlying,” “parallel,” “perpendicular,” etc., are intended to describe relative locations as they are oriented and illustrated in the drawings (unless otherwise indicated) and terms such as “touching,” “in direct contact,” “abutting,” “directly adjacent to,” “immediately adjacent to,” etc., are intended to indicate that at least one element physically contacts another element (without other elements separating the described elements). The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element. The corresponding structures, materials, acts, and equivalents of all means or step plus function elements in the claims below are intended to include any structure, material, or act for performing the function in combination with other claimed elements as specifically claimed.

The descriptions of the various disclosed embodiments have been presented for purposes of illustration but are not intended to be exhaustive or limiting. Many modifications and variations will be apparent to those of ordinary skill in the art without departing from the scope and spirit of the disclosed embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
an input terminal;
an output terminal; and
series-connected transistors between the input terminal and the output terminal,
wherein a first section of the series-connected transistors is connected to the input terminal,
wherein a second section of the series-connected transistors is connected between the first section and the output terminal, and
wherein the first section is devoid of over-gate gaps and the second section includes the over-gate gaps.

2. The structure of claim 1, wherein transistor layout lengths are longer in the second section than in the first section.

3. The structure of claim 1, wherein transistor gate-to-source/drain contact spacings are larger in the second section than in the first section.

4. The structure of claim 1, wherein transistor layout widths are equal in the first section and in the second section.

5. The structure of claim 1, further comprising compensation capacitors, wherein the compensation capacitors are coupled to at least some of the series-connected transistors in the first section.

6. The structure of claim 5, wherein none of the compensation capacitors are coupled to the series-connected transistors in the second section.

7. The structure of claim 5, wherein the compensation capacitors coupled to the series-connected transistors within each sub-section of the first section have progressively decreasing sizes.

8. The structure of claim 7, wherein the compensation capacitors include metal-insulator-metal capacitors.

9. The structure of claim 1, wherein the series-connected transistors include semiconductor-on-insulator n-channel field effect transistors with multiple gate fingers.

10. The structure of claim 1,
wherein the first section and at least one sub-section of the second section include partially interdigitated source and drain interconnects, and
wherein at least a last transistor in the second section and connected to the output terminal includes non-interdigitated source and drain interconnects.

11. A structure comprising:
an input terminal;
an output terminal; and
series-connected transistors between the input terminal and the output terminal,
wherein a first section of the series-connected transistors is connected to the input terminal,
wherein a second section of the series-connected transistors is connected between the first section and the output terminal,
wherein transistor layout lengths are longer in the second section than in the first section,
wherein transistor gate-to-source/drain contact spacings are larger in the second section than in the first section, and
wherein the first section is devoid of over-gate gaps and the second section includes the over-gate gaps.

12. The structure of claim 1₁, wherein the first section has sub-sections and wherein the transistor layout lengths increase across the sub-sections from the input terminal to the second section.

13. The structure of claim 1₁, wherein transistor layout widths are equal in the first section and in the second section.

14. The structure of claim 1₁, further comprising compensation capacitors, wherein the compensation capacitors are coupled to at least some of the series-connected transistors in the first section.

15. The structure of claim 14, wherein none of the compensation capacitors are coupled to the series-connected transistors in the second section.

16. The structure of claim 15,
wherein the first section has sub-sections,
wherein the transistor layout lengths increase across the sub-sections from the input terminal to the second section, and
wherein the compensation capacitors coupled to the series-connected transistors within each sub-section of the first section have progressively decreasing sizes.

17. The structure of claim 15, wherein the compensation capacitors include metal-insulator-metal capacitors.

18. The structure of claim 1₁, wherein the series-connected transistors include semiconductor-on-insulator n-channel field effect transistors with multiple gate fingers.

19. The structure of claim 1₁,
wherein the first section and at least one sub-section of the second section include partially interdigitated source and drain interconnects, and
wherein at least a last transistor in the second section and connected to the output terminal includes non-interdigitated source and drain interconnects.

20. A structure comprising:
an input terminal;
an output terminal; and
series-connected transistors between the input terminal and the output terminal,
wherein the series-connected transistors include semiconductor-on-insulator n-channel field effect transistors with multiple gate fingers,
wherein a first section of the series-connected transistors is connected to the input terminal,
wherein a second section of the series-connected transistors is connected between the first section and the output terminal,
wherein transistor layout lengths are longer in the second section than in the first section,
wherein transistor gate-to-source/drain contact spacings are larger in the second section than in the first section, and
wherein the first section is devoid of over-gate gaps and the second section includes the over-gate gaps.
